(19) United States
(12) Patent Application Publication
(10) Pub. No.: US 2026/0066002 A1
(43) Pub. Date: Mar. 5, 2026

(54) MEMORY STORAGE APPARATUS AND METHOD FOR READING MEMORY STORAGE APPARATUS

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/001,531

(22) Filed: Dec. 25, 2024

(30) Foreign Application Priority Data
Sep. 3, 2024 (TW) 113133303

(51) Int. Cl. G11C 16/26; G11C 16/08; G11C 16/32

(52) U.S. Cl. CPC G11C 16/26; G11C 16/08; G11C 16/32

(57) ABSTRACT

A memory storage device including a memory cell array and a controller circuit is provided. The memory cell array includes a plurality of first memory cells. The controller circuit is coupled to the memory cell array. The controller circuit is configured to adjust a first waiting period and a first conduction period and read data stored in the first memory cells according to the first waiting period and the first conduction period until the first memory cells achieve a read pass. When the controller circuit adjusts the first waiting period to a target waiting time length and adjusts the first conduction period to a target conduction time length, the first memory cells achieve the read pass.

### CROSS-REFERENCE TO RELATED APPLICATION

This application claims the priority benefit of Taiwan application serial no. 113133303, filed on Sep. 3, 2024. The entirety of the above-mentioned patent application is hereby incorporated by reference herein and made a part of this specification.

### BACKGROUND

### Technical Field

The disclosure relates to an electronic apparatus and an operation method thereof, and particularly relates to a memory storage apparatus and a reading method thereof.

### Description of Related Art

In a memory storage apparatus, such as a flash memory, signature cells are first read during a power on sequence. Only after these signature cells are successfully read (achieve a read pass), can the option cells be read. However, in the existing memory storage apparatus, the waiting period and the conduction period for reading the signature cells cannot be adjusted. As a result, while the signature cells may achieve the read pass, subsequent reading of the option cells may fail due to power noise and power drop.

### SUMMARY

The disclosure provides a memory storage apparatus and a reading method thereof, which may adjust a waiting period and a conduction period for reading memory cells, so as to correctly read the memory cells.

According to an embodiment of the disclosure, a memory storage apparatus includes a memory cell array and a controller circuit. The memory cell array includes a plurality of first memory cells. The controller circuit is coupled to the memory cell array. The controller circuit is configured to adjust a first waiting period and a first conduction period and read data stored in the first memory cells according to the first waiting period and the first conduction period until the first memory cells achieve a read pass. When the controller circuit adjusts the first waiting period to a target waiting time length and adjusts the first conduction period to a target conduction time length, the first memory cells achieve the read pass.

According to an embodiment of the disclosure, a reading method of a memory storage apparatus includes: setting an initial waiting period and an initial conduction period as a first waiting period and a first conduction period; reading data stored in first memory cells according to the first waiting period and the first conduction period; determining whether the first memory cells achieve the read pass; when the first memory cells do not achieve the read pass, adjusting the first waiting period and the first conduction period until the first memory cells achieve the read pass.

To make the above-mentioned features and advantages of the disclosure more comprehensible, embodiments are described in detail below with reference to the accompanying drawings.

### BRIEF DESCRIPTION OF THE DRAWINGS

FIG. 1 and FIG. 2 are schematic block diagrams illustrating memory storage apparatuses according to different embodiments of the disclosure.

FIG. 3 is a schematic diagram illustrating a memory cell array according to the embodiment shown in FIG. 2.

FIG. 4 is a schematic waveform diagram of word line signals and switch control signals according to an embodiment of the disclosure.

FIG. 5 is a flowchart of steps in a reading method of a memory storage apparatus according to an embodiment of the disclosure.

### DESCRIPTION OF THE EMBODIMENTS

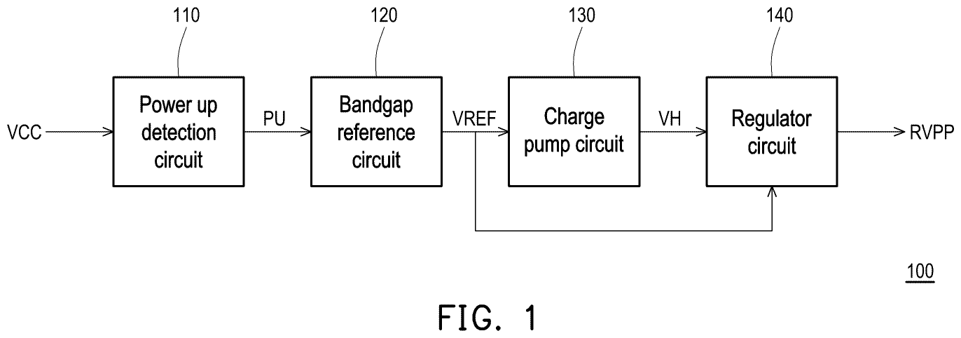

FIG. 1 is a schematic block diagram illustrating a memory storage apparatus according to an embodiment of the disclosure. With reference to FIG. 1, a flash memory is taken as an example, and FIG. 1 illustrates a power on sequence of a memory storage apparatus 100.

First, a power up detection circuit 110 detects a power supply VCC and outputs a power up signal PU accordingly. The power up signal PU is configured to activate a bandgap reference circuit 120 and enable the bandgap reference circuit 120 to generate a reference voltage VREF for a charge pump circuit 130 and a regulator circuit 140. The charge pump circuit 130 generates a high voltage signal VH based on the reference voltage VREF. Next, the regulator circuit 140 generates a voltage signal RVPP based on the reference voltage VREF and the high voltage signal VH. The voltage signal RVPP may be provided to a word line decoder circuit as an operating voltage.

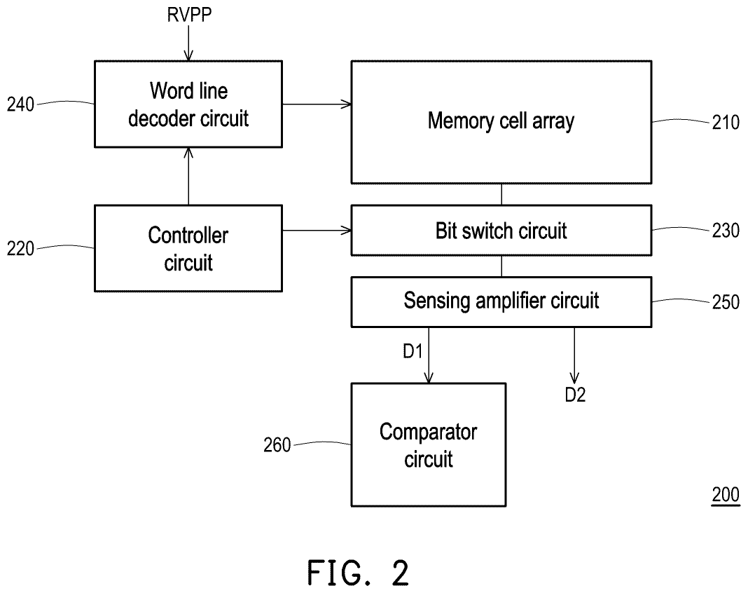

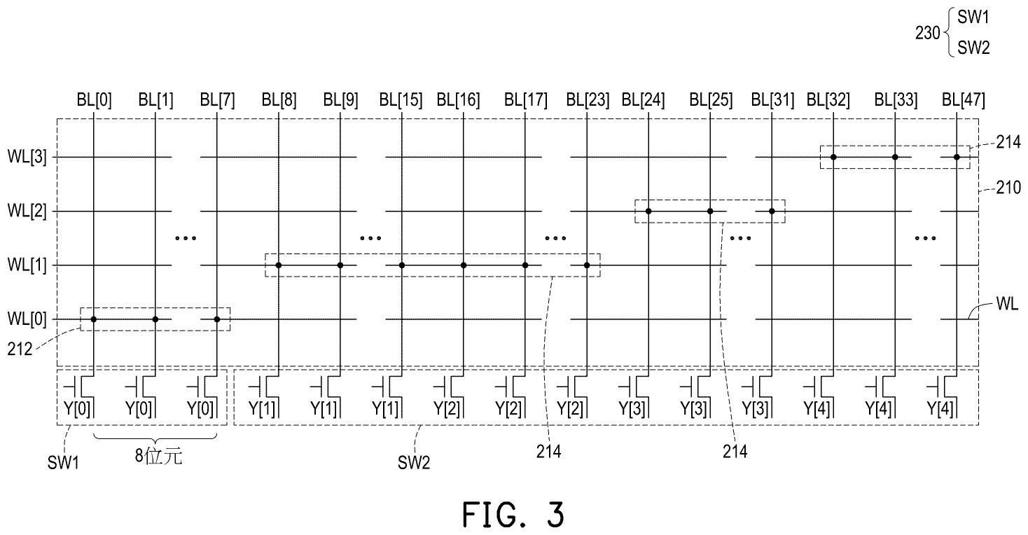

FIG. 2 is a schematic block diagram illustrating a memory storage apparatus according to another embodiment of the disclosure. FIG. 3 is a schematic diagram illustrating a memory cell array according to the embodiment shown in FIG. 2. With reference to FIG. 2 and FIG. 3, a memory storage apparatus 200 includes a memory cell array 210, a controller circuit 220, a bit switch circuit 230, a word line decoder circuit 240, a sensing amplifier circuit 250, and a comparator circuit 260. The controller circuit 220 is coupled to the memory cell array 210.

The memory cell array 210 includes a plurality of first memory cells 212 and a plurality of second memory cells 214. The first memory cells 212 are, for instance, signature cells. The first memory cells 212 are memory cells located on the same word line WL. The second memory cells 214 are, for instance, option cells. The second memory cells 214 may be memory cells located on different word lines WL. The signature cells 212 are configured, for instance, to store specific data. The specific data must be read during the power on sequence. Usually, during the execution of a power on reading operation, applying an appropriate reading voltage may ensure the reading of correct data.

The word line decoder circuit 240 is coupled to the memory cell array 210 through a plurality of word lines WL. The word line decoder circuit 240 is configured to output a plurality of word line signals WL[0], WL[1], WL[2], and WL[3] to turn on the corresponding word lines WL. The memory storage apparatus 200 may, for instance, utilize the power on sequence shown in FIG. 1 to generate the voltage signal RVPP for the word line decoder circuit 240 as an operating voltage.

The bit switch circuit 230 is coupled to the memory cell array 210 through bit lines. The bit switch circuit 230 includes a plurality of first switch devices SW1 and a plurality of second switch devices SW2. The first switch devices SW1 are coupled to the first memory cells 212 through bit lines BL[0] to BL[7]. The second switch devices SW2 are coupled to the second memory cells 214 through bit lines BL[8] to BL[47].

The controller circuit 220 is configured to output control signals Y[0], Y[1], Y[2], Y[3], and Y[4] to control a conduction state of the first switch devices SW1 and the second switch devices SW2. When the first switch devices SW1 are turned on, the data D1 stored in the first memory cells 212 may be read out. When the second switch devices SW2 are turned on, the data D2 stored in the second memory cells 214 may be read out.

Regarding the hardware structure of elements depicted in FIG. 1 and FIG. 2, the controller circuit 220 may be a processor with computational capabilities. As an alternative, the controller circuit 220 may be designed using hardware description language (HDL) or any other digital circuit design method familiar to those skilled in the pertinent art, and the controller circuit 220 may be a hardware circuit implemented through a field programmable gate array (FPGA), a complex programmable logic device (CPLD), or an application-specific integrated circuit (ASIC). Besides, referring to the common knowledge in the pertinent field, sufficient teaching, suggestions, and implementation instructions for the hardware structure of the word line decoder circuit 240, the sensing amplifier circuit 250, and the comparator circuit 260 may be obtained.

Moreover, in FIG. 3, the number of the word lines, the bit lines, the memory cells, and the switch devices serve to exemplify the invention and should not be intended to limit the scope of this invention.

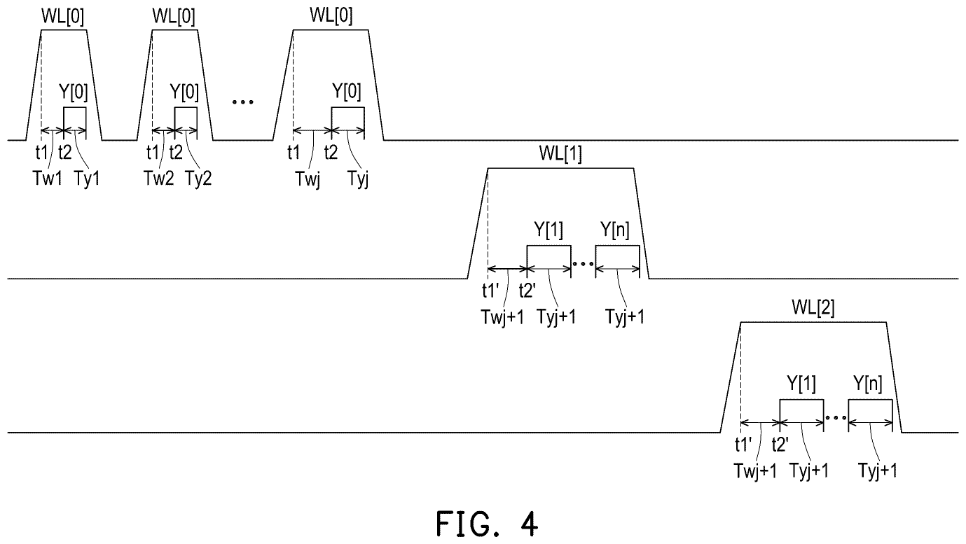

FIG. 4 is a schematic waveform diagram of word line signals and switch control signals according to an embodiment of the invention. With reference to FIG. 2 to FIG. 4, the controller circuit 220 reads the data D1 stored in the first memory cells 212 during a power up period, and the controller circuit 220 starts to read the data D2 stored in the second memory cells 214 after the first memory cells 212 achieve the read pass.

Specifically, during the power up period, the controller circuit 220 reads the data D1 stored in the first memory cells 212, and the sensing amplifier circuit 250 is applied to perform a sensing operation. Subsequently, the comparator circuit 260 determines whether the read data D1 are correct. If the read data D1 are correct, it indicates that the first memory cells 212 achieve the read pass. Conversely, if the read data D1 are incorrect, it indicates that the first memory cells 212 fail to complete the reading (i.e., encounter a read fail).

In this embodiment, the controller circuit 220 may adjust first waiting periods Tw1 to Twj and first conduction periods Ty1 to Tyj and read the data D1 stored in the first memory cells 212 according to the first waiting periods Tw1 to Twj and the first conduction periods Ty1 to Tyj until the first memory cells 212 achieve the read pass.

When the data D1 stored in the first memory cells 212 are read for the first time, the controller circuit 220 may, for instance, set an initial waiting period and an initial conduction period as the first waiting period Tw1 and the first conduction period Ty1. The controller circuit 220 reads the data D1 stored in the first memory cells 212 according to the first waiting period Tw1 and the first conduction period Ty1. Assuming the first read fails, the controller circuit 220 increases the time length of the first waiting period Tw1 and the time length of the first conduction period Ty1 to the first waiting period Tw2 and the first conduction period Ty2, respectively. Here, the time length of the first waiting period Tw2 is greater than the time length of the first waiting period Tw1, and the time length of the first conduction period Ty2 is greater than the time length of the first conduction period Ty1. Next, the controller circuit 220 re-reads the data D1 stored in the first memory cells according to the first waiting period Tw2 and the first conduction period Ty2.

Therefore, the controller circuit 220 may continuously increase the time length of the first waiting period and the time length of the first conduction period until the first memory cells 212 achieve the read pass. For instance, when the controller circuit 220 adjusts the first waiting period Twj to a target waiting time length (i.e., the width of Twj) and adjusts the first conduction period Tyj to a target conduction time length (i.e., the width of Tyj), the first memory cells 212 achieve the read pass. Consequently, the first waiting period Twj is a waiting period during which the first memory cells 212 achieve the read pass, and the first conduction period Tyj is a conduction period during which the first memory cells 212 achieve the read pass.

When the first memory cells 212 achieve the read pass, the controller circuit 220 may set the second waiting period Twj+1 to be greater than the target waiting time length Twj and set the second conduction period Tyj+1 to be greater than the target conduction time length Tyj. Next, the controller circuit 220 reads the data D2 stored in the second memory cells 214 according to the second waiting period Twj+1 and the second conduction period Tyj+1.

Since the controller circuit 220 has already enabled the first memory cells 212 to achieve the read pass based on the first waiting period Twj and the first conduction period Tyj when reading the first memory cells 212, by setting the second waiting period Twj+1 to be greater than the target waiting time length Twj and setting the second conduction period Tyj+1 to be greater than the target conduction time length Tyj, the controller circuit 220 may be ensured to correctly read the second memory cells 214.

In FIG. 4, the control signal Y[0] is a control signal for controlling the conduction state of the first switch devices SW1. For instance, during a period when the control signal Y[0] is at a high level, the first switch devices SW1 may be turned on. Therefore, the first conduction periods Ty1, Ty2, . . . , and Tyj are the conduction periods of the first switch devices SW1.

Since the controller circuit 220 may read the data D1 stored in the first memory cells 212 multiple times and adjust the first conduction periods Ty1, Ty2, . . . , and Tyj until the first memory cells 212 achieve the read pass, the time length of each of the first conduction periods Ty1, Ty2, . . . , and Tyj applied by the controller circuit 220 to read the first memory cells 212 may be different, e.g., becoming increasingly longer.

The control signals Y[1] to Y[n] are control signals for controlling the conduction state of the second switch devices SW2, where n is an integer greater than 1. For instance, during the period when the control signals Y[1] to Y[n] are at a high level, the second switch devices SW2 may be turned on. Therefore, the second conduction period Tyj+1 is the conduction period of the second switch devices SW2.

To ensure the correct reading of the second memory cells 214, the time length of the second conduction period Tyj+1 applied by the controller circuit 220 to read the second memory cells 214 located on different bit lines may be the same. For instance, when reading the second memory cells 214 located on the bit lines BL[8] to BL[23], the time length of the second conduction period Tyj+1 corresponding to the respective second switch devices SW2 may all be the same.

On the other hand, in FIG. 4, the word line decoder circuit 240 outputs the word line signals WL[0], WL[1], WL[2], and WL[3] to turn on the word lines WL. The word lines WL being turned on means that the word line signals applied to the word lines WL are at an enabling period, e.g., a high level period or a low level period. In FIG. 4, the high level period of the word line signals WL[0], WL[1], WL[2], and WL[3] is the enabling period. Here, the first waiting periods Tw1 to Twj are from the initial conduction time of the word lines WL to the initial conduction time of the first switch devices SW1.

Taking the first waiting period Tw1 as an example, the initial conduction time of the word line WL corresponding to the word line signal WL[0] is t1, and the initial conduction time of the first switch devices SW1 is t2. A time interval between the time t1 and the time t2 is the first waiting period Tw1.

Since the controller circuit 220 may read the data D1 stored in the first memory cells 212 multiple times and adjust the first waiting periods T Ty1, Ty2, . . . , and Tyj until the first memory cells 212 achieve the read pass, the time length of each of the first waiting periods Ty1, Ty2, . . . , and Tyj applied by the controller circuit 220 to read the first memory cells 212 may be different, e.g., becoming increasingly longer. Moreover, the time length of the word line signal WL[0] may also be different each time.

Additionally, the second waiting period Twj+1 is from the initial conduction time of the word lines WL to the initial conduction time of the second switch devices SW2. Taking the second waiting period Twj+1 of the word line signal WL[1] as an example, the initial conduction time of the word line WL corresponding to the word line signal WL[1] is t1′, and the initial conduction time of the second switch devices SW2 is t2′. A time interval between the time t1′ and the time t2′ is the second waiting period Twj+1.

To ensure the correct reading of the second memory cells 214, the time length of the second waiting period Twj+1 applied by the controller circuit 220 to read the second memory cells 214 located on different word lines may all be the same. For instance, the second memory cells 214 may be located on different word lines WL corresponding to the word line signals WL[1] and WL[2], and the time length of each second waiting period Twj+1 configured to read the second memory cells 214 may all be the same.

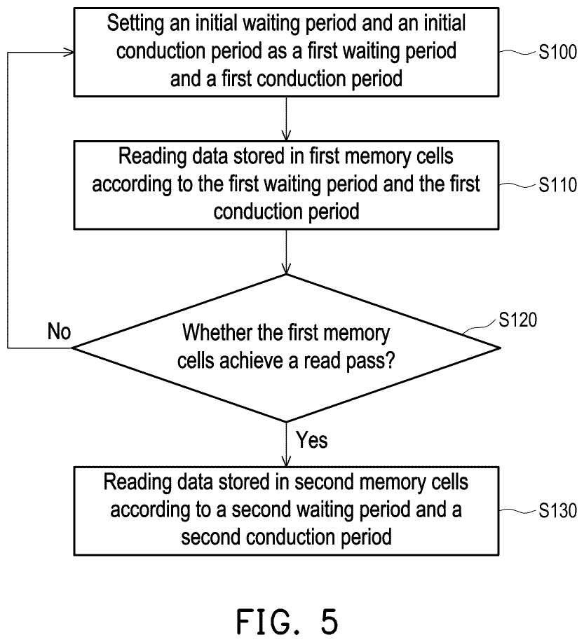

FIG. 5 is a flowchart of steps in a reading method of a memory storage apparatus according to an embodiment of the disclosure. With reference to FIG. 2 to FIG. 5, the reading method of the memory storage apparatus provided in this embodiment may be suitable for the memory storage apparatus 200 in FIG. 2, which should however not be construed as a limitation in the disclosure.

Taking the memory storage apparatus 200 as an example, in step S100, the controller circuit 220 sets the initial waiting period and the initial conduction period as the first waiting period Tw1 and the first conduction period Ty1. In step S110, the controller circuit 220 reads the data D1 stored in the first memory cells 212 according to the first waiting period Tw1 and the first conduction period Ty1. In step S120, the comparator circuit 260 determines whether the first memory cells 212 achieve the read pass. If the read data D1 are correct, it indicates that the first memory cells 212 achieve the read pass, and step S130 in the reading method is performed. In step S130, the controller circuit 220 reads the data D2 stored in the second memory cells 214 according to the second waiting period Twj+1 and the second conduction period Tyj+1.

On the contrary, if the read data D1 are incorrect, it indicates that the first memory cells 212 encounter the read fail, and step S100 in the reading method is again performed to adjust the first waiting period and the first conduction period until the first memory cells 212 achieve the read pass.

Moreover, the reading method of the memory storage apparatus provided in one or more embodiments of the disclosure embodiment may be sufficiently taught, suggested, and explained for implementation from the descriptions provided in the embodiments depicted in FIG. 1 to FIG. 4, and therefore no further elaboration is provided hereinafter.

To sum up, in one or more of the embodiments of the disclosure, the controller circuit may adjust the waiting period and the conduction period for reading the first memory cells until the first memory cells achieve the read pass. Next, the controller circuit may set the waiting period and the conduction period applied for reading the second memory cells to be greater than the waiting period and the conduction period applied for reading the first memory cells. As a result, the controller circuit may correctly read the second memory cells, thus reducing the impact of power noise and power drop on the read results.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory storage apparatus, comprising:
a memory cell array, comprising a plurality of first memory cells; and
a controller circuit, coupled to the memory cell array and configured to adjust a first waiting period and a first conduction period and read data stored in the first memory cells according to the first waiting period and the first conduction period until the first memory cells achieve a read pass,
wherein when the controller circuit adjusts the first waiting period to a target waiting time length and adjusts the first conduction period to a target conduction time length, the first memory cells achieve the read pass.

2. The memory storage apparatus according to claim 1, wherein the memory cell array further comprises a plurality of second memory cells, and the controller circuit reads data stored in the second memory cells according to a second waiting period and a second conduction period,
wherein the second waiting period is greater than the target waiting time length, and the second conduction period is greater than the target conduction time length.

3. The memory storage apparatus according to claim 2, further comprising:
a bit switch circuit, comprising a plurality of first switch devices coupled to the first memory cells, wherein the first conduction period is a conduction period of the first switch devices.

4. The memory storage apparatus according to claim 3, further comprising:
a word line decoder circuit, coupled to the memory cell array through a plurality of word lines and configured to output a plurality of word line signals to the word lines, so as to turn on the word lines, wherein the first waiting period is from an initial conduction time of the word lines to an initial conduction time of the first switch devices.

5. The memory storage apparatus according to claim 3, wherein the bit switch circuit further comprises a plurality of second switch devices coupled to the second memory cells, wherein the second conduction period is a conduction period of the second switch devices.

6. The memory storage apparatus according to claim 5, further comprising:
a word line decoder circuit, coupled to the memory cell array through a plurality of word lines and configured to output a plurality of word line signals to the word lines, so as to turn on the word lines, wherein the second waiting period is from an initial conduction time of the word lines to an initial conduction time of the second switch devices.

7. The memory storage apparatus according to claim 2, wherein time lengths of the second waiting period for reading the second memory cells located on different word lines are all the same, and time lengths of the second conduction period for reading the second memory cells located on different bit lines are all the same.

8. The memory storage apparatus according to claim 2, wherein the controller circuit reads the data stored in the first memory cells during a power on reading period, and the controller circuit starts to read the data stored in the second memory cells after the first memory cells achieve the read pass.

9. The memory storage apparatus according to claim 1, wherein the controller circuit reads the data stored in the first memory cells multiple times until the first memory cells achieve the read pass, wherein a time length of the first waiting period for each reading of the first memory cells is different, and a time length of the first conduction period for each reading of the first memory cells is different.

10. The memory storage apparatus according to claim 9, wherein the first memory cells are located on one word line.

11. A reading method of a memory storage apparatus, wherein the memory storage apparatus comprises a memory cell array, and the memory cell array comprises a plurality of first memory cells and a plurality of second memory cells, the reading method of the memory storage apparatus comprising:
setting an initial waiting period and an initial conduction period as a first waiting period and a first conduction period;
reading data stored in first memory cells according to the first waiting period and the first conduction period;
determining whether the first memory cells achieve the read pass; and
when the first memory cells do not achieve the read pass, adjusting the first waiting period and the first conduction period until the first memory cells achieve the read pass.

12. The reading method of the memory storage apparatus according to claim 11, wherein the memory cell array further comprises a plurality of second memory cells, and the operating method further comprises:
when the first memory cells achieve the read pass, reading data stored in the second memory cells according to a second waiting period and a second conduction period,
wherein the second waiting period is greater than the target waiting time length, and the second conduction period is greater than the target conduction time length.

13. The reading method of the memory storage apparatus according to claim 12, wherein the second conduction period is a conduction period of a plurality of second switch devices of the memory storage apparatus.

14. The reading method of the memory storage apparatus according to claim 13, wherein the second waiting period is from an initial conduction time of a plurality of word lines of the memory storage apparatus to an initial conduction time of the second switch devices.

15. The reading method of the memory storage apparatus according to claim 12, wherein time lengths of the second waiting period for reading the second memory cells located on different word lines are all the same, and time lengths of the second conduction period for reading the second memory cells located on different bit lines are all the same.

16. The reading method of the memory storage apparatus according to claim 11, wherein the first conduction period is a conduction period of a plurality of first switch devices of the memory storage apparatus.

17. The reading method of the memory storage apparatus according to claim 16, wherein the first waiting period is from an initial conduction time of a plurality of word lines of the memory storage apparatus to an initial conduction time of the first switch devices.

18. The reading method of the memory storage apparatus according to claim 16, wherein a time length of the first waiting period for each reading of the first memory cells is different, and a time length of the first conduction period for each reading of the first memory cells is different.

19. The reading method of the memory storage apparatus according to claim 11, wherein the reading method of the memory storage apparatus is performed during a power on reading period.

20. The reading method of the memory storage apparatus according to claim 19, wherein the first memory cells are located on one word line.
